(19) United States
(12) Patent Application Publication
(10) Pub. No.: US 2026/0244359 A1
(43) Pub. Date: Aug. 20, 2026

(54) ELECTRONIC DEVICE INCLUDING STORAGE DEVICE

(71) Applicant: SK hynix Inc., Gyeonggi-do (KR)

(72) Inventors: Dong Sop LEE, Gyeonggi-do (KR); Soo Jin KIM, Gyeonggi-do (KR)

(21) Appl. No.: 19/358,440

(22) Filed: Oct. 15, 2025

(30) Foreign Application Priority Data
Feb. 17, 2025 (KR) 10-2025-0020398
Apr. 29, 2025 (KR) 10-2025-0056250

(51) Int. Cl. G06F 3/06

(52) U.S. Cl. CPC G06F 3/0655; G06F 3/061; G06F 3/0679

(57) ABSTRACT

An electronic device includes a first package substrate, a storage device including a plurality of memory dies stacked over the first package substrate and a vertical connector connected to the plurality of memory dies, and a host disposed on the first package substrate and configured to control the storage device. The storage device and the host are configured to communicate within the first package substrate.

### CROSS-REFERENCE TO RELATED APPLICATIONS

The present application claims priority under 35 U.S.C. § 119(a) to Korean patent application number 10-2025-0020398, filed on Feb. 17, 2025 and Korean patent application number 10-2025-0056250, filed on April 29, 2025, the entire disclosures of which are incorporated herein by reference.

### BACKGROUND

### Technical Field

Various embodiments of the present disclosure generally relate to an electronic device, and more particularly, to an electronic device including a host and a storage device included in the same package.

### Related Art

A storage device is a device which stores data under the control of a host device, such as a computer, a smartphone, or a smart pad. The storage device may include a memory device in which data is stored, and a memory controller which stores data in the memory device. Memory devices can be categorized into a volatile memory device or a non-volatile memory device.

When the host device and the storage device are included in different packages, the need for signal transmission between physically separate packages can result in a longer transmission path and more signal interference. This can quickly saturate the bandwidth of inter-package communication during spikes in data transfer volume when applications which require high-speed data transfers are running, causing performance degradation of electronic devices including the host device and the storage device.

### SUMMARY

Various embodiments of the present disclosure are directed to an electronic device including a host and a storage device included in the same package.

An electronic device according to embodiments of the present disclosure may include a first package substrate, a storage device including a plurality of memory dies which are stacked over the first package substrate and a vertical connector connected to the plurality of memory dies, and a host disposed on the first package substrate and configured to control the storage device. The storage device and the host may communicate within the first package substrate.

In one or more embodiments, the storage device may include an insulating layer including a redistribution layer, a base die disposed on the insulating layer, the plurality of memory dies disposed on the base die, and the vertical connector configured to connect the plurality of memory dies and the redistribution layer.

In one or more embodiments, the vertical connector may be disposed to extend in a straight line in a direction perpendicular to the first package substrate.

In one or more embodiments, the insulating layer may further include a first interface circuit configured to support die-to-die communication with the host, and the insulating layer may be disposed on the first package substrate.

In one or more embodiments, the first package substrate, the first interface circuit, and a second interface circuit disposed in the host may provide a communication path between the host and the storage device.

In one or more embodiments, the electronic device may further include an interposer substrate disposed on the first package substrate, and the storage device and the host may be disposed on the interposer substrate.

In one or more embodiments, the insulating layer may be disposed between the first package substrate and the interposer substrate. The interposer substrate, the first interface circuit, and a second interface circuit disposed in the host may provide a communication path between the host and the storage device.

In one or more embodiments, the host and the storage device may communicate based on the same protocol layer.

In one or more embodiments, the protocol layer may include one of a network layer supporting an Advanced eXtensible Interface (Axi), a data link layer supporting Universal Chiplet Interconnect Express (UCIe), and a physical layer. The first and second interface circuits may support UCIe-based communication.

In one or more embodiments, the storage device may include a memory controller corresponding to the base die and a non-volatile memory device corresponding to the plurality of memory dies, and the memory controller. The non-volatile memory device may be configured to communicate a data signal and a data strobe signal via unidirectional buses.

In one or more embodiments, the memory controller may be configured to output a first data signal to the non-volatile memory device via a first data bus, and output a first data strobe signal to the non-volatile memory device via a first data strobe bus. The non-volatile memory device may be configured to output a second data signal to the memory controller via a second data bus, and output a second data strobe signal to the memory controller via a second data strobe bus.

In one or more embodiments, the first data bus may include first data pins and a first transmission line, the first data strobe bus may include first data strobe pins and a second transmission line, the second data bus may include second data pins and a third transmission line, and the second data strobe bus may include second data strobe pins and a fourth transmission line.

In one or more embodiments, the first data signal may include at least one of a command instructing an operation to be performed by the non-volatile memory device, address information for accessing the non-volatile memory device, and write data to be stored in the non-volatile memory device. The first data strobe signal may be a timing reference signal output from the memory controller to the non-volatile memory device along with the first data signal. The second data signal may include at least one of an indication of whether the operation corresponding to the command has been completed, an indication of whether an error has occurred, identification data of the non-volatile memory device, and read data read from the non-volatile memory device. The second data strobe signal may be a timing reference signal output from the non-volatile memory device to the memory controller along with the second data signal.

In one or more embodiments, the electronic device may further include a second package substrate including a volatile memory device configured to communicate with the host.

In one or more embodiments, the electronic device may further include a second package substrate including a volatile memory device configured to communicate with the storage device.

In one or more embodiments, the first package substrate may further include a volatile memory device. The volatile memory device may include a plurality of memory dies which are stacked and a vertical connector connected to the plurality of memory dies. The first package substrate may provide a communication path between the host and the volatile memory device.

In one or more embodiments, the host may include a third interface circuit supporting UCIe, and may be configured to communicate with the volatile memory device via the third interface circuit.

In one or more embodiments, the electronic device may further include a volatile memory device disposed on the base die. The volatile memory device may include a plurality of memory dies which are stacked and a vertical connector connected to the plurality of memory dies.

In one or more embodiments, the first package substrate may provide a communication path between the volatile memory device and the host.

In one or more embodiments, the plurality of memory dies may be stacked with an offset.

### BRIEF DESCRIPTION OF THE DRAWINGS

FIG. 1 is a block diagram of an electronic device according to embodiments of the present disclosure;

FIG. 2 is a block diagram of an electronic device according to a first embodiment of the present disclosure;

FIG. 3 is a cross-sectional view of a first package according to the first embodiment of the present disclosure;

FIG. 4 is a perspective view of a first package according to the first embodiment of the present disclosure;

FIG. 5 is a perspective view of a first package according to the first embodiment of the present disclosure;

FIG. 6 is a detailed block diagram of a host and a memory controller of FIG. 2;

FIG. 7 is a detailed block diagram of a signal transmission path between a memory controller and a memory device of FIG. 1;

FIG. 8 is a perspective view of an electronic device according to the first embodiment of the present disclosure;

FIG. 9 is a block diagram of an electronic device according to a second embodiment of the present disclosure;

FIG. 10 is a perspective view of an electronic device according to the second embodiment of the present disclosure;

FIG. 11 is a block diagram of an electronic device according to a third embodiment of the present disclosure;

FIG. 12 is a perspective view of an electronic device according to the third embodiment of the present disclosure;

FIG. 13 is a block diagram of an electronic device according to a fourth embodiment of the present disclosure; and

FIG. 14 is a perspective view of an electronic device according to the fourth embodiment of the present disclosure.

### DETAILED DESCRIPTION

Hereinafter, embodiments according to the present disclosure are described in detail with reference to the accompanying drawings. It should be noted that in the following description, only portions necessary for understanding an operation according to the present disclosure may be described, and descriptions of other portions may be omitted in order not to obscure the subject matter of the present disclosure. In addition, the present disclosure may be embodied in other forms without being limited to embodiments described herein. However, embodiments of the present disclosure are described in detail in order for those skilled in the art to be able to readily implement the technical spirit of the present disclosure.

Throughout the specification, in a case where a certain portion “includes” a certain component, the portion may further include another component without excluding another component unless otherwise stated. “At least any one of X, Y, or Z” and “at least any one selected from a group consisting of X, Y, or Z” may be interpreted as X only, Y only, Z only, or any combination of two or more of X, Y, and Z (for example, XYZ, XYY, YZ, and ZZ). Here, “and/or” includes all combinations of one or more of corresponding configurations.

Here, terms such as first and second may be used to describe various components, but these components are not limited to these terms. These terms are used to distinguish one component from another component. Therefore, a first component may refer to a second component within a range without departing from the scope disclosed herein.

In this field, some embodiments are described and illustrated in the accompanying drawings in terms of functional blocks, units, parts, and/or modules. Those skilled in the art will understand that these blocks, units, parts, and/or modules are physically implemented by electronic (or optical) circuits, such as logic circuits, discrete components, microprocessors, hard-wired circuits, memory elements, line connections, and the like, which may be formed using semiconductor-based manufacturing techniques or other manufacturing techniques. In a case where the blocks, units, parts, and/or modules are implemented by microprocessors or other similar hardware, they may be programmed and controlled using software (e.g., microcode) to perform the various functions discussed herein, and may optionally be driven by firmware and/or software.

Further, each block, unit, part, and/or module may be implemented by dedicated hardware, or by a combination of dedicated hardware performing some functions and processors (e.g., one or more programmed microprocessors and associated circuit) performing other functions. Further, each block, unit, portion, and/or module of some embodiments may be physically separated into two or more interacting and separate blocks, units, portions, and/or modules without departing from the scope of the present disclosure. Further, the blocks, units, portions, and/or modules of some embodiments may be physically combined into more complex blocks, units, portions, and/or modules without departing from the scope of the present disclosure.

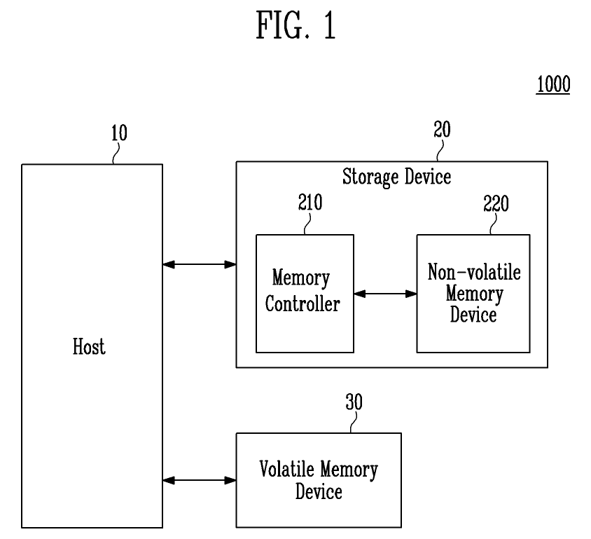

FIG. 1 is a block diagram of an electronic device 1000 according to embodiments of the present disclosure.

Referring to FIG. 1, the electronic device 1000 may include a host 10, a storage device 20, and a volatile memory device 30.

The electronic device 1000 may be a computing device configured to process various information or store processed information as data. In some embodiments, the electronic device 1000 may be implemented as a personal computer (PC), a notebook, a laptop, a server, a workstation, a tablet PC, a smartphone, a digital camera, a dashcam, or the like.

The host 10 may control various operations of the electronic device 1000. More specifically, the host 10 may control operations of other components which constitute the electronic device 1000. The host 10 may be implemented as a general purpose processor, a dedicated processor, an application processor (AP), or the like.

The host 10 may communicate with the storage device 20. For example, the host 10 may output a command to the storage device 20 to request that the storage device 20 perform a program operation, a read operation, an erase operation, or the like. The host 10 may transmit a host request, data, and a logical address to the storage device 20 for the program operation of the storage device 20. The host 10 may transmit a host request and a logical address to the storage device 20 for the read operation of the storage device 20.

The storage device 20 may store data. For example, the storage device 20 may store data under the control of the host 10. In some embodiments, the storage device 20 may include at least one of a solid state drive (SSD), embedded memory, or removable external memory.

The storage device 20 may include a memory controller 210 and a non-volatile memory device 220. The memory controller 210 may control the operation of the storage device 20. For example, the memory controller 210 may control the operation of the storage device 20 in accordance with an internal policy or in response to a request from the host 10. The memory controller 210 may store data in the non-volatile memory device 220 or read data stored in the non-volatile memory device 220 in accordance with an internal policy or in response to a request from the host 10.

The memory controller 210 may, in response to a host request corresponding to a program operation received from the host 10, generate a program command and provide the generated program command to the non-volatile memory device 220. The memory controller 210 may, in response to a host request corresponding to a read operation received from the host 10, generate a command and provide the generated command to the non-volatile memory device 220. The memory controller 210 may transmit data read from the non-volatile memory device 220 to the host 10.

The non-volatile memory device 220 may store data under the control of the memory controller 210. The non-volatile memory device 220 may include a plurality of memory blocks (not shown). Each of the plurality of memory blocks may include a plurality of memory cells, and the plurality of memory cells may constitute a plurality of strings or a plurality of pages.

The non-volatile memory device 220 may move or copy data to perform various functions. For example, the non-volatile memory device 220 may move or copy data between memory blocks of the non-volatile memory device 220 to perform at least one of a garbage collection operation, a read reclaim operation, a read refresh operation, a wear leveling operation, or an over-provision operation.

The non-volatile memory device 220 may be NAND flash memory, but the scope of the present disclosure is not limited thereto. The non-volatile memory device 220 may be one of a variety of storage devices which may retain stored data even when supplied power is interrupted, such as Phase-change Random Access Memory (PRAM), Magnetic Random Access Memory (MRAM), Resistive Random Access Memory (RRAM), Ferroelectric Random Access Memory (FRAM), and the like.

The host 10 may communicate with the volatile memory device 30. For example, the host 10 may request that the volatile memory device 30 perform a program operation, a read operation, an erase operation, or the like.

The volatile memory device 30 may store data. For example, the volatile memory device 30 may store instructions and data which are executed and processed by the control of the host 10. The volatile memory device 30 may be implemented as memory having a relatively fast operating speed. For example, the volatile memory device 30 may include a volatile memory such as Dynamic Random Access Memory (DRAM).

The host 10, the storage device 20, and the volatile memory device 30 may each be included in different packages. Hereinafter, being included in different packages may refer to being included in different package substrates. Also, being included in the same package may refer to being included in the same package substrate.

As the host 10, the storage device 20, and the volatile memory device 30 are each included in different packages, the host 10 may communicate with the storage device 20 and the volatile memory device 30 via interfaces which support inter-package communication. For example, the host 10 and the storage device 20 may communicate via interfaces such as Universal Flash Storage (UFS) and embedded Multi-Media Card (eMMC). Additionally, the host 10 and the volatile memory device 30 may communicate via interfaces such as a Low Power Double Data Rate Physical Layer (LPDDR PHY).

However, interfaces which support inter-package communication may provide relatively low bandwidth compared to die-to-die communication. This is because inter-package communication requires signal transmission between physically separated packages, resulting in a longer transmission path and more signal interference. As a result, when running applications that require high-speed data transfers, bandwidth of inter-package communication may quickly saturate during spikes in data transfer volume, which may degrade the performance of the electronic device 1000.

Die-to-die communication, on the other hand, takes place within a single physical chip (die), resulting in a shorter signal transmission path and less signal interference or transmission loss. As a result, die-to-die communication may provide higher bandwidth and a faster data transfer speed, which is suitable for real-time processing. In addition, die-to-die communication may minimize or reduce transmission latency, making it more suitable for applications which require real-time data processing or high-speed data transfer.

However, when using inter-package communication, the communication between the host 10 and the storage device 20 and the communication between the host 10 and the volatile memory device 30 may not meet the speed or latency demands required for real-time processing. To overcome these limitations, the electronic device 1000 may be required which allows the host 10 to communicate with the storage device 20 or volatile memory device 30 via an interface which supports die-to-die communication.

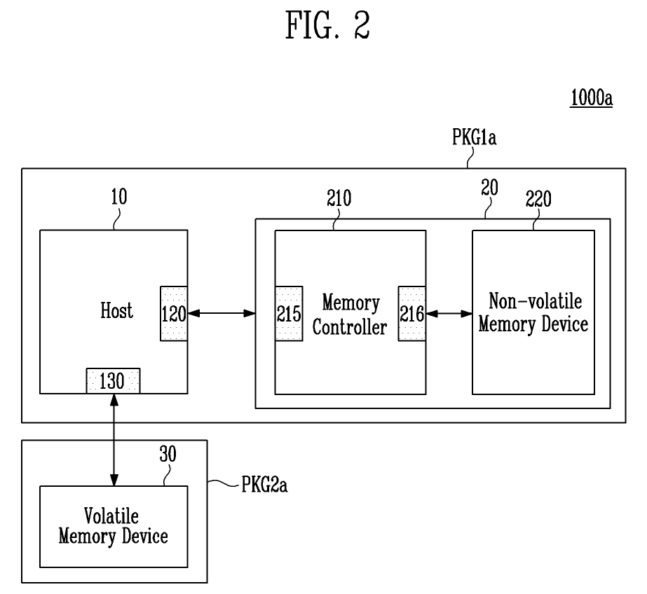

FIG. 2 is a block diagram of an electronic device 1000a according to a first embodiment of the present disclosure.

Referring to FIG. 2, the host 10 and the storage device 20 may be included in a first package PKG1a, and the volatile memory device 30 may be included in a second package PKG2a.

The host 10, the storage device 20, and the volatile memory device 30 of FIG. 2 are similar to the host 10, the storage device 20, and the volatile memory device 30 of FIG. 1, and thus repetitive descriptions are omitted.

The electronic device 1000a may include the first package PKG1a including the host 10 and the storage device 20, and the second package PKG2a including the volatile memory device 30.

As the host 10 and the storage device 20 are included in the first package PKG1a, the host 10 and the storage device 20 may transmit and receive signals to and from each other via lines on a substrate included in the first package PKG1a.

In an embodiment, the host 10 and the storage device 20 may communicate via a device interface circuit 120 of the host 10 and a device interface circuit 215 of the memory controller 210. Each of the device interface circuit 120 of the host 10 and the device interface circuit 215 of the memory controller 210 may be implemented based on an interface which supports die-to-die communication. For example, each of the device interface circuit 120 of the host 10 and the device interface circuit 215 of the memory controller 210 may be implemented based on Universal Chiplet Interconnect Express (UCIe).

The electronic device 1000a, which includes the host 10 and the storage device 20 included in the first package PKG1a, may provide higher bandwidth and a faster data transfer speed than an electronic device supporting inter-package communication, and may be suitable for real-time processing.

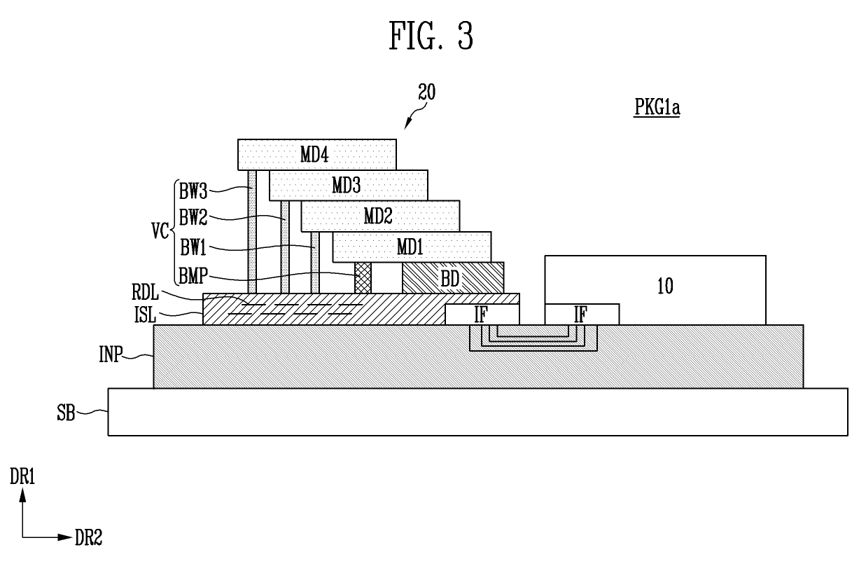

The storage device 20 may have a structure in which a plurality of dies are stacked (for example, with an offset from each die below that may create a non-aligned vertical pattern). Further, the storage device 20 may include a vertical connector which is connected to the plurality of dies. A detailed structure of the storage device 20 will be described below with reference to FIGS. 3 to 5.

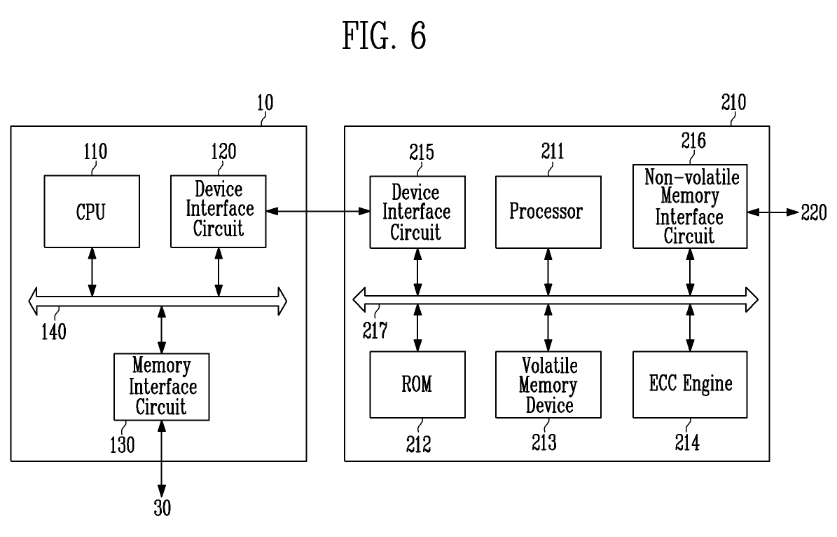

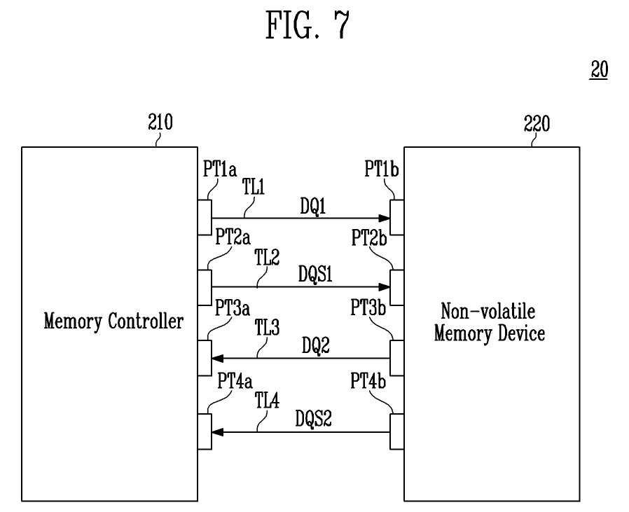

The storage device 20 may include the memory controller 210 and the non-volatile memory device 220. The memory controller 210 may communicate with the non-volatile memory device 220 via a non-volatile memory interface circuit 216, which will be described in more detail hereinbelow with reference to FIGS. 6 and 7.

Because the host 10 and the volatile memory device 30 are included in different packages, the host 10 and the volatile memory device 30 may transmit and receive signals via transmission lines connecting the first package PKG1a and the second package PKG2a.

In an embodiment, the host 10 may communicate with the volatile memory device 30 included in the second package PKG2a via a memory interface circuit 130 which supports inter-package communication. For example, the memory interface circuit 130 may be implemented based on Low Power Double Data Rate (LPDDR) interface, which will be described in more detail hereinbelow with reference to FIG. 6.

FIG. 3 is a cross-sectional view of the first package PKG1a according to the first embodiment of the present disclosure.

Referring to FIG. 3, the host 10 and the storage device 20 may be included in the first package PKG1a.

The first package PKG1a may include a package substrate SB, an interposer substrate INP, the host 10, and the storage device 20. In a first direction DR1, the interposer substrate INP may be arranged (for example, disposed) on the package substrate SB. In the first direction DR1, the host 10 and the storage device 20 may be arranged on the interposer substrate INP. The first direction DR1 may be a direction perpendicular to the package substrate SB. The host 10 and the storage device 20 may be arranged in a second direction DR2 parallel to the package substrate SB.

The package substrate SB may provide an electrical connection to an external circuit board of the electronic device 1000a and may serve to supply power and a control signal to the electronic device 1000a. The package substrate SB may also provide a physical support structure for the interposer substrate INP, the host 10, and the storage device 20.

The interposer substrate INP may be arranged on the package substrate SB. The interposer substrate INP may include a wiring structure which enables data communication between the host 10 and the storage device 20. For example, the interposer substrate INP may provide a die-to-die communication path between the host 10 and the storage device 20.

The host 10 and the storage device 20 may be arranged on the interposer substrate INP.

The storage device 20 may include an insulating layer ISL, a plurality of memory dies MD1, MD2, MD3, and MD4, a base die BD, and a vertical connector VC.

The storage device 20 may have a structure in which the plurality of memory dies MD1, MD2, MD3, and MD4 and the base die BD are stacked (for example, with an offset), and may include the vertical connector VC connected to the plurality of memory dies MD1, MD2, MD3, and MD4.

In each of the plurality of memory dies MD1, MD2, MD3, and MD4, memory cells for storing data and circuits for operating the memory cells may be arranged. The base die BD may include a controller which controls the plurality of memory dies MD1, MD2, MD3, and MD4.

In an embodiment, the plurality of memory dies MD1, MD2, MD3, and MD4 may correspond to the non-volatile memory device 220 of FIGS. 1 and 2. For example, the non-volatile memory device 220 may include a memory cell corresponding to each of the plurality of memory dies MD1, MD2, MD3, and MD4. The base die BD may correspond to the memory controller 210 of FIGS. 1 and 2.

The vertical connector VC may be a connecting member extending in the first direction DR1. The first direction DR1 may be perpendicular to the package substrate SB. The vertical connector VC may extend in the first direction DR1 in a straight, unbent line. The vertical connector VC may include a conductive material to provide pathways for electrical signals to be connected to the plurality of memory dies MD1, MD2, MD3, and MD4. The vertical connector VC may include a conductive metallic material such as gold (Au) or copper (Cu).

The vertical connector VC may include first to third bonding wires BW1, BW2, and BW3 and a conductive bump BMP. The conductive bump BMP may be formed including a copper (Cu) material.

The plurality of memory dies MD1, MD2, MD3, and MD4 and the base die BD may be arranged sequentially over the insulating layer ISL. For example, in the first direction DR1, the base die BD, the first memory die MD1, the second memory die MD2, the third memory die MD3, and the fourth memory die MD4 may be arranged sequentially over the interposer substrate INP.

In each of the plurality of memory dies MD1, MD2, MD3, and MD4, memory cells for storing data and circuits for operating the memory cells may be arranged. The base die BD may include a controller which controls the plurality of memory dies MD1, MD2, MD3, and MD4.

Each of the plurality of memory dies MD1, MD2, MD3, and MD4 may be connected to a redistribution layer RDL via the vertical connector VC. For example, the first memory die MD1 may be connected to the redistribution layer RDL via the conductive bump BMP, the second memory die MD2 may be connected to the redistribution layer RDL via the first bonding wire BW1, the third memory die MD3 may be connected to the redistribution layer RDL via the second bonding wire BW2, and the fourth memory die MD4 may be connected to the redistribution layer RDL via the third bonding wire BW3.

The redistribution layer RDL may include conductive patterns which are electrically and signal-wise connected to the vertical connector VC. The redistribution layer RDL may include circuit lines which are connected to the plurality of memory dies MD1, MD2, MD3, and MD4 and the base die BD via the vertical connector VC.

The redistribution layers RDL may be insulated from each other by the insulating layer ISL. The redistribution layer RDL may be an interconnection structure, such as a Printed Circuit Board (PCB).

An interface circuit IF supporting die-to-die communication with the host 10 may be formed in the insulating layer ISL. Further, the interface circuit IF supporting die-to-die communication with the storage device 20 may be formed in the host 10.

The interposer substrate INP may include a wiring layer and a via structure for communication between semiconductor dies. The interposer substrate INP, the interface circuit IF formed in the insulating layer ISL, and the interface circuit IF formed in the host 10 may provide a communication path between the host 10 and the storage device 20.

The interface circuit IF formed in the host 10 and the interface circuit IF formed in the storage device 20 may each include a physical layer and a link layer for transmitting and receiving data. For example, the interface circuit IF may support UCIe-based communication.

FIG. 3 illustrates that there is one each of the first to third bonding wires BW1 to BW3 and the conductive bump BMP, but the present disclosure is not limited thereto, and according to embodiments, one or more of each of the first to third bonding wires BW1 to BW3 and the conductive bump BMP may be provided. For example, the second memory die MD2 may be connected to the redistribution layer RDL via a plurality of first bonding wires BW1.

Also, referring to FIG. 3, while the storage device 20 is shown to include four memory dies MD1 to MD4, the present disclosure is not limited thereto and the storage device 20 may include one or more memory dies according to embodiments.

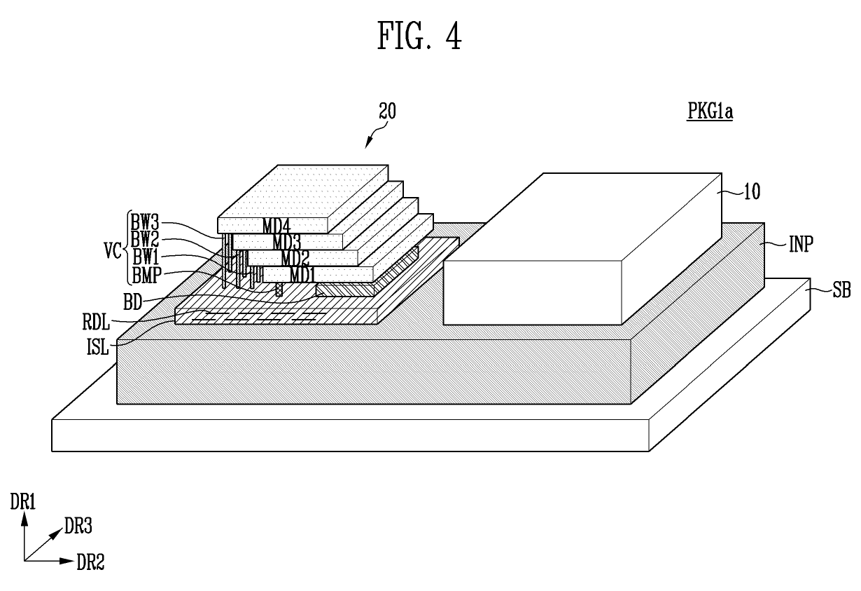

FIG. 4 is a perspective view of the first package PKG1a according to the first embodiment of the present disclosure.

Referring to FIG. 4, the host 10 and the storage device 20 may be included in the first package PKG1a.

The package substrate SB, the interposer substrate INP, the host 10, and the storage device 20 of FIG. 4 are similar to the package substrate SB, the interposer substrate INP, the host 10, and the storage device 20 of FIG. 3, so that repetitive descriptions may be omitted.

The first package PKG1a may include the package substrate SB, the interposer substrate INP, the host 10, and the storage device 20. In the first direction DR1, the interposer substrate INP may be arranged on the package substrate SB. In the first direction DR1, the host 10 and the storage device 20 may be arranged on the interposer substrate INP.

The interposer substrate INP, an interface circuit (for example interface circuit IF described herein above, not shown in FIG. 4) formed in the storage device 20, and an interface circuit formed in the host 10 may provide a communication path between the host 10 and the storage device 20.

One or more each of the first to third bonding wires BW1 to BW3 and the conductive bump BMP may be provided. For example, the first memory die MD1 may be connected to the redistribution layer RDL via a plurality of conductive bumps BMP. The plurality of conductive bumps BMP may be arranged in a third direction DR3 (for example, parallel to the surface of the package substrate SB, perpendicular to both directions DR1 and DR2).

The second memory die MD2 may be connected to the redistribution layer RDL via a plurality of first bonding wires BW1. The plurality of first bonding wires BW1 may be arranged in the third direction DR3.

The third memory die MD3 may be connected to the redistribution layer RDL via a plurality of second bonding wires BW2. The plurality of second bonding wires BW2 may be arranged in the third direction DR3.

The fourth memory die MD4 may be connected to the redistribution layer RDL via a plurality of third bonding wires BW3. The plurality of third bonding wires BW3 may be arranged in the third direction DR3.

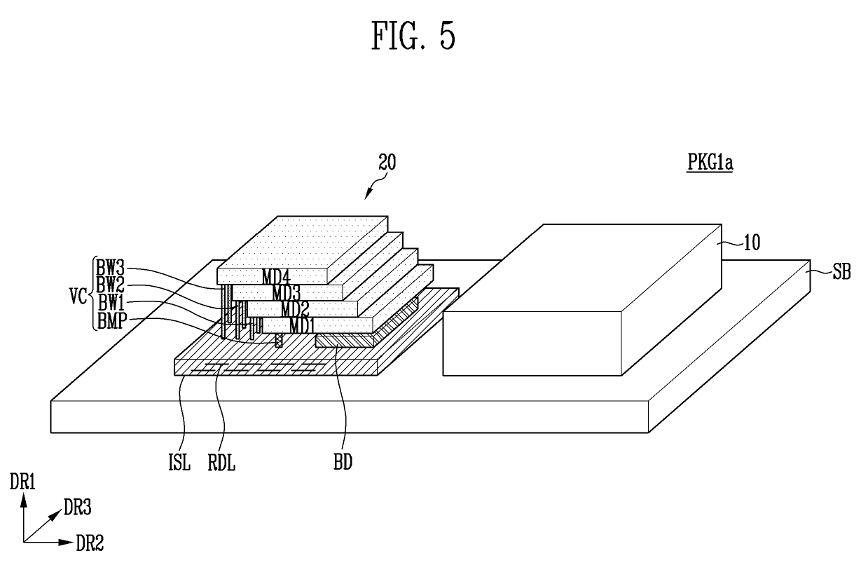

FIG. 5 is a perspective view of the first package PKG1a according to the first embodiment of the present disclosure.

Referring to FIG. 5, the host 10 and the storage device 20 may be included in the first package PKG1a.

The package substrate SB, the host 10, and the storage device 20 of FIG. 5 are similar to the package substrate SB, the host 10, and the storage device 20 of FIG. 3, so that repetitive descriptions may be omitted.

The first package PKG1a may include the package substrate SB, the host 10, and the storage device 20. In the second direction DR2, the host 10 and the storage device 20 may be arranged on the package substrate SB.

Referring to FIG. 3, the interface circuit IF supporting die-to-die communication with the host 10 may be formed in the insulating layer ISL. In addition, the interface circuit IF supporting die-to-die communication with the storage device 20 may be formed in the host 10.

The package substrate SB may include a wiring layer and a via structure for communication between semiconductor dies. The package substrate SB, the interface circuit formed in the storage device 20, and the interface circuit formed in the host 10 may provide a communication path between the host 10 and the storage device 20.

Each of the interface circuit formed in the host 10 and the interface circuit formed in the storage device 20 may include a physical layer and a link layer for transmitting and receiving data. For example, the interface circuit formed in the host 10 and the interface circuit formed in the storage device 20 may each support UCIe-based communication.

Referring to FIGS. 3 to 5, the host 10 and the storage device 20 may be included in the single package substrate SB to form the first package PKG1a. Accordingly, the host 10 may communicate with the storage device 20 via an interface supporting die-to-die communication, and the electronic device 1000a including the first package PKG1a may provide higher bandwidth and a faster data transfer speed than an electronic device which supports inter-package communication, and may be suitable for real-time processing.

FIG. 6 is a detailed block diagram of the host 10 and the memory controller 210 of FIG. 2.

Referring to FIG. 6, the host 10 may communicate with the memory controller 210.

The host 10 and the memory controller 210 of FIG. 6 may be similar to the host 10 and the memory controller 210 of FIG. 2. Accordingly, repetitive descriptions may be omitted.

The host 10 may include a central processing unit (CPU) 110, the device interface circuit 120, the memory interface circuit 130, and a first bus 140. The CPU 110, the device interface circuit 120, and the memory interface circuit 130 may transmit and receive data to and from each other via the first bus 140.

The CPU 110 operates within the host 10 and may control the electronic device 1000a in response to a data processing request generated by a user (for example, via a user interface) or the electronic device 1000a. Specifically, the CPU 110 may generate a request to store, retrieve, or delete data, and may transmit a command corresponding to the request to the storage device 20. The CPU 110 may interpret response data received from the storage device 20 and perform necessary subsequent processing or transfer the response data to other components of the electronic device 1000a.

The host 10 may communicate with the memory controller 210 via the device interface circuit 120. The device interface circuit 120 may be the interface circuit IF formed in the host 10 shown in FIG. 3. The device interface circuit 120 may be implemented based on an interface which supports die-to-die communication. For example, the device interface circuit 120 may be implemented based on UCIe.

The host 10 may communicate with the volatile memory device 30 via the memory interface circuit 130. Referring to FIG. 2, unlike the host 10, the volatile memory device 30 may be included in the second package PKG2a. Accordingly, the memory interface circuit 130 may be implemented based on an interface that supports inter-package communication. For example, the memory interface circuit 130 may be implemented based on Low Power Double Data Rate (LPDDR) interface. The memory interface circuit 130 may include a physical layer circuit for transmitting and receiving a signal in accordance with an LPDDR protocol.

The memory controller 210 may include a processor 211, Read Only Memory (ROM) 212, a volatile memory device 213, an error correction code (ECC) engine 214, the device interface circuit 215, the non-volatile memory interface circuit 216, and a second bus 217.

The processor 211, the ROM 212, the volatile memory device 213, the ECC engine 214, the device interface circuit 215, and the non-volatile memory interface circuit 216 may transmit and receive data to and from each other via the second bus 217.

The processor 211 may control various operations of the memory controller 210. The processor 211 may execute firmware to control the operation of the memory controller 210. The processor 211 may execute (run) firmware loaded on the volatile memory device 213 to control various operations of the memory controller 210 and perform logical operations.

The firmware is a program which is executed in the storage device 20 and may include various functional layers. For example, the firmware may include at least one of a Flash Translation Layer (FTL), a Host Interface Layer (HIL), or a Flash Interface Layer (FIL). The FTL serves to translate a Logical Address required by the host 10 for the storage device 20 into a Physical Address of the non-volatile memory device 220 or vice versa. The HIL interprets a command requested by the host 10 to the non-volatile memory device 220 and transfers the interpreted command to the FTL. The FIL transfers a command instructed by the FTL to the non-volatile memory device 220.

The ROM 212 may be used as read-only memory to store information required for an operation of the memory controller 210. The volatile memory device 213 may be used as main memory, cache memory, or operational memory of the memory controller 210. For example, the volatile memory device 213 may be implemented as Static Random Access Memory (SRAM), Dynamic Random Access Memory (DRAM), or the like.

The ECC engine 214 may detect and correct errors in data read from the non-volatile memory device 220. For example, the ECC engine 214 may have a certain level of error correction capability. The ECC engine 214 may treat data having an error level (e.g., the number of flipped bits) which exceeds the error correction capability as uncorrectable data.

The memory controller 210 may communicate with the host 10 via the device interface circuit 215. In an embodiment, the device interface circuit 120 of the host 10 may be electrically connected to the device interface circuit 215 of the memory controller 210 to transmit and receive a command or data.

The device interface circuit 215 may be the interface circuit IF formed in the insulating layer ISL shown in FIG. 3. The device interface circuit 215 may be implemented based on an interface which supports die-to-die communication. For example, the device interface circuit 215 may be implemented based on UCIe.

The host 10 and the memory controller 210 may perform die-to-die communication within the first package PKG1a. The communication between the host 10 and the memory controller 210 may be carried out directly based on a custom protocol (an internal memory map structure or communication scheme) defined by the host 10, without going through a separate transport protocol layer or standardized interface protocol.

That is, the host 10 and the memory controller 210 may transmit and receive data based on the same protocol layer. The protocol layer may include a network layer supporting an Advanced eXtensible Interface (Axi), a data link layer supporting UCIe, and a physical layer. The host 10 may directly access the memory controller 210 based on the custom protocol of the host 10. Such access may include a memory access request and response signal.

As described with reference to FIG. 6, in the present disclosure, the host 10 and the storage device 20 may communicate over the protocol layer including the network layer supporting an Axi, the data link layer supporting UCIe, and the physical layer. Further, each of the host 10 and the storage device 20 may include an interface circuit including the data link layer supporting UCIe, and the physical layer. Accordingly, repetitive descriptions of the configuration and operation of the protocol layer and interface circuit may be omitted from this disclosure.

As the host 10 and the memory controller 210 communicate over the same protocol, the communication latency between the host 10 and the memory controller 210 may be minimized or reduced and the interface complexity may be reduced. As the host 10 and the memory controller 210 perform die-to-die communication within the first package PKG1a, the performance of the electronic device 1000a may be improved.

The memory controller 210 may communicate with the non-volatile memory device 220 via the non-volatile memory interface circuit 216. In some embodiments, the non-volatile memory interface circuit 216 may be implemented based on an interface which supports die-to-die communication.

In other words, the non-volatile memory interface circuit 216 may be implemented based on UCIe, rather than based on traditional NAND Flash interfaces such as Toggle and Open NAND Flash Interface (ONFI), which will be described in more detail below with reference to FIG. 7.

FIG. 7 is a detailed block diagram of a signal transmission path between the memory controller 210 and the non-volatile memory device 220 of FIG. 1.

Referring to FIG. 7, the memory controller 210 of FIG. 1 outputs a first data signal DQ1 and a first data strobe signal DQS1 to the non-volatile memory device 220, and the memory controller 210 may receive a second data signal DQ2 and a second data strobe signal DQS2 from the non-volatile memory device 220.

The memory controller 210 and the non-volatile memory device 220 may be connected to each other via first data pins PT1a and PT1b, first data strobe pins PT2a and PT2b, second data pins PT3a and PT3b, and second data strobe pins PT4a and PT4b, each forming a corresponding pair between the memory controller 210 and the non-volatile memory device 220.

The memory controller 210 may output the first data signal DQ1 to the non-volatile memory device 220 via the first data pins PT1a and PT1b and a first transmission line TL1. The first data signal DQ1 may include at least one of a command instructing an operation to be performed by the non-volatile memory device 220, address information for accessing the non-volatile memory device 220, and write data to be stored in the non-volatile memory device 220.

The memory controller 210 may output the first data strobe signal DQS1 to the non-volatile memory device 220 via the first data strobe pins PT2a and PT2b and a second transmission line TL2. The first data strobe signal DQS1 may be a timing reference signal output from the memory controller 210 to the non-volatile memory device 220 along with the first data signal DQ1. The non-volatile memory device 220 may set a sampling time point of the first data signal DQ1 based on the first data strobe signal DQS1.

The non-volatile memory device 220 may receive the second data signal DQ2 from the memory controller 210 via the second data pins PT3a and PT3b and a third transmission line TL3. The second data signal DQ2 may include at least one of (an indication of) whether an operation corresponding to a command has been completed, (an indication of) whether an error has occurred, identification data of the non-volatile memory device 220 (e.g., manufacturer ID, device ID, memory capacity information), or read data which is read from the non-volatile memory device 220.

The non-volatile memory device 220 may output the second data strobe signal DQS2 to the memory controller 210 via the second data strobe pins PT2a and PT2b and a fourth transmission line TL4. The second data strobe signal DQS2 may be a timing reference signal output from the non-volatile memory device 220 to the memory controller 210 along with the second data signal DQ2. The memory controller 210 may set a sampling time point of the second data signal DQ2 based on the second data strobe signal DQS2.

The first data pins PT1a and PT1b and the first transmission line TL1 may be referred to as a first data bus, the first data strobe pins PT2a and PT2b and the second transmission line TL2 may be referred to as a first data strobe bus, the second data pins PT3a and PT3b and the third transmission line TL3 may be referred to as a second data bus, and the second data strobe pins PT4a and PT4b and the fourth transmission line TL4 may be referred to as a second data strobe bus.

That is, each of the first data bus, the first data strobe bus, the second data bus, and the second data strobe bus shown in FIG. 7 may be implemented as a unidirectional bus.

Accordingly, in the storage device 20 including the memory controller 210 and the non-volatile memory device 220 of FIG. 7, the signal transmission efficiency may be improved compared to a storage device in which the first data bus and the second data bus are integrated into one bus and implemented as a bidirectional bus, and the first data strobe bus and the second data strobe bus are integrated into one bus and implemented as a bidirectional bus. That is, faster signal transmission is possible while consuming less power. For example, the bidirectional buses may require additional circuitry to switch between receiving and sending data, which may introduce latency and additional signal integrity issues.

As described with reference to FIG. 7, the die-to-die communication described herein may be performed via the first data bus, the first data strobe bus, the second data bus, and the second data strobe bus each of which is implemented as a unidirectional bus.

For example, the die-to-die communication between the host 10 and the storage device 20 of FIG. 2, and the die-to-die communication between the memory controller 210 and the non-volatile memory device 220 may be performed via the first data bus, the first data strobe bus, the second data bus, and the second data strobe bus each of which is implemented as a unidirectional bus.

Although the first data bus, the first data strobe bus, the second data bus, and the second data strobe bus connecting the memory controller 210 and the non-volatile memory device 220 are shown in FIG. 7, the present disclosure is not limited thereto, and additional separate buses may be provided between the memory controller 210 and the non-volatile memory device 220, according to embodiments. For example, additional buses for outputting a Command Latch Enable (CLE) signal, an Address Latch Enable (ALE) signal, and a clock signal from the memory controller 210 to the non-volatile memory device 220 may be provided.

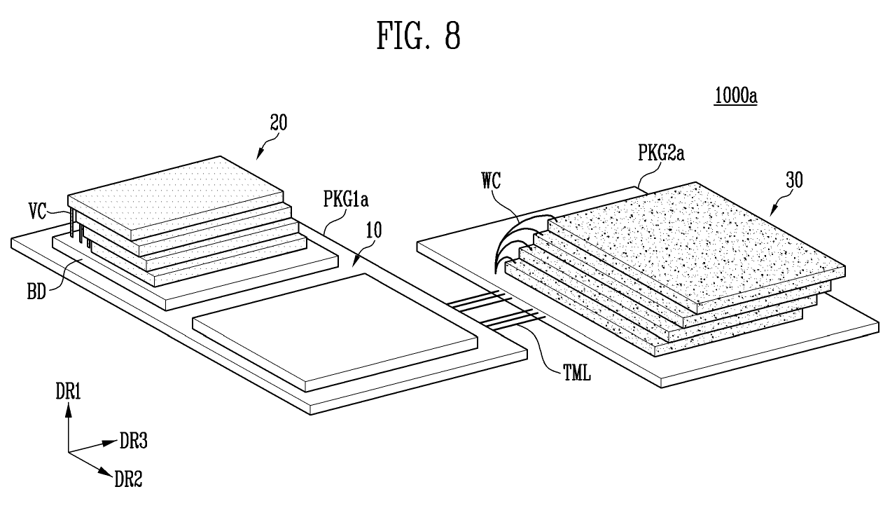

FIG. 8 is a perspective view of the electronic device 1000a according to the first embodiment of the present disclosure.

Referring to FIG. 8, the electronic device 1000a may include the first package PKG1a including the host 10 and the storage device 20, and the second package PKG2a including the volatile memory device 30.

The host 10, the storage device 20, and the volatile memory device 30 of FIG. 8 are similar to the host 10, the storage device 20, and the volatile memory device 30 of FIG. 2, and thus repetitive descriptions are omitted.

The first package PKG1a of FIG. 8 may be similar to one of the first packages PKG1a of FIG. 4 and 5. Accordingly, repetitive descriptions may be omitted.

The storage device 20 included in the first package PKG1a may have a structure in which a plurality of memory dies and the base die BD are stacked, and may include the vertical connector VC connected to the plurality of memory dies.

Also, for convenience of illustration, the base die BD of FIG. 8 may be represented in a configuration which includes the base die BD, the redistribution layer RDL, and the insulating layer ISL shown in FIGS. 3 to 5.

The volatile memory device 30 included in the second package PKG2a may have a structure in which a plurality of memory dies and a base die are stacked, and may include a wire connector WC connected to the plurality of memory dies.

The wire connector WC may be formed along a curved path bent in the first direction DR1, unlike the vertical connector VC, which extends vertically in the first direction DR1.

Because the host 10 and the storage device 20 are included in the same package, the host 10 and the storage device 20 may transmit and receive signals to and from each other via lines on the substrate included in the first package PKG1a, i.e., the host 10 and the storage device 20 may perform die-to-die communication.

As the host 10 and the volatile memory device 30 are included in different packages, the host 10 and the volatile memory device 30 may transmit and receive signals via transmission lines TML connecting the first package PKG1a and the second package PKG2a.

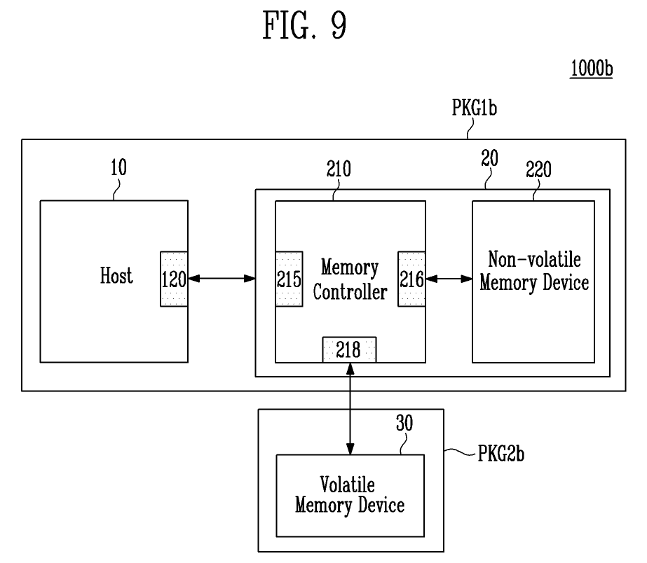

FIG. 9 is a block diagram of an electronic device 1000b according to a second embodiment of the present disclosure.

Referring to FIG. 9, the host 10 and the storage device 20 may be included in a first package PKG1b, and the volatile memory device 30 may be included in a second package PKG2b.

The host 10, the storage device 20, and the volatile memory device 30 of FIG. 9 are similar to the host 10, the storage device 20, and the volatile memory device 30 of FIG. 1, and thus repetitive descriptions are omitted.

The electronic device 1000b may include the first package PKG1b including the host 10 and the storage device 20, and the second package PKG2b including the volatile memory device 30.

As the host 10 and the storage device 20 are included in the first package PKG1b, the host 10 and the storage device 20 may transmit and receive signals to and from each other via lines on a substrate included in the first package PKG1b. In an embodiment, the host 10 and the storage device 20 may communicate via the device interface circuit 120 of the host 10 and the device interface circuit 215 of the memory controller 210.

As described with reference to FIG. 6, each of the device interface circuit 120 of the host 10 and the device interface circuit 215 of the memory controller 210 may be implemented based on an interface which supports die-to-die communication. For example, each of the device interface circuit 120 of the host 10 and the device interface circuit 215 of the memory controller 210 may be implemented based on UCIe.

The electronic device 1000b, which includes the host 10 and the storage device 20 included in the first package PKG1b, may provide higher bandwidth and a faster data transfer speed than an electronic device supporting inter-package communication, and may be suitable for real-time processing.

The storage device 20 may have a structure in which a plurality of dies are stacked. Further, the storage device 20 may include a vertical connector which is connected to the plurality of dies. The detailed structure of the storage device 20 may be similar to that described with reference to FIGS. 3 to 5.

The storage device 20 may include the memory controller 210 and the non-volatile memory device 220. The memory controller 210 may communicate with the non-volatile memory device 220 via the non-volatile memory interface circuit 216. As described with reference to FIG. 7, the memory controller 210 and the non-volatile memory device 220 may perform die-to-die communication via the first data bus, the first data strobe bus, the second data bus, and the second data strobe bus each of which is implemented as a unidirectional bus.

Because the storage device 20 and the volatile memory device 30 are included in different packages, the storage device 20 and the volatile memory device 30 may transmit and receive signals via transmission lines (not shown) connecting the first package PKG1b and the second package PKG2b.

In an embodiment, the memory controller 210 may communicate with the volatile memory device 30 included in the second package PKG2b via a memory interface circuit 218 which supports inter-package communication. For example, the memory interface circuit 218 may be implemented based on Low Power Double Data Rate (LPDDR) interface.

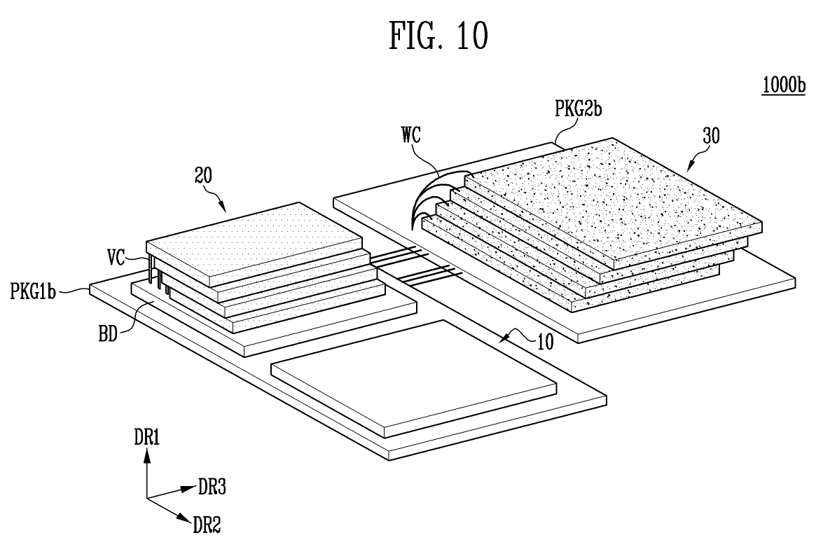

FIG. 10 is a perspective view of the electronic device 1000b according to the second embodiment of the present disclosure.

Referring to FIG. 10, the electronic device 1000b may include the first package PKG1b including the host 10 and the storage device 20, and the second package PKG2b including the volatile memory device 30.

The host 10, the storage device 20, and the volatile memory device 30 of FIG. 10 may be similar to the host 10, the storage device 20, and the volatile memory device 30 of FIG. 9. Accordingly, repetitive descriptions may be omitted.

Further, the first package PKG1b of FIG. 10 may be similar to one of the first packages PKG1a of FIGS. 4 and 5. The second package PKG2b of FIG. 10 may be similar to the second package PKG2a of FIG. 8. Accordingly, repetitive descriptions may be omitted.

The storage device 20 included in the first package PKG1b may have a structure in which the plurality of memory dies and the base die BD are stacked, and may include the vertical connector VC connected to the plurality of memory dies.

Additionally, for convenience of illustration, the base die BD of FIG. 10 may be represented in a configuration which includes the base die BD, the redistribution layer RDL, and the insulating layer ISL shown in FIGS. 3 to 5.

The volatile memory device 30 included in the second package PKG2b may have a structure in which a plurality of memory dies and a base die are stacked, and may include the wire connector WC connected to the plurality of memory dies.

The wire connector WC may be formed along a curved path bent in the first direction DR1, unlike the vertical connector VC, which extends vertically in the first direction DR1.

Because the host 10 and the storage device 20 are included in the same package, the host 10 and the storage device 20 may transmit and receive signals to and from each other via lines on the substrate included in the first package PKG1b, i.e., the host 10 and the storage device 20 may perform die-to-die communication.

As the storage device 20 and the volatile memory device 30 are included in different packages, the storage device 20 and the volatile memory device 30 may transmit and receive signals via transmission lines connecting the first package PKG1b and the second package PKG2b.

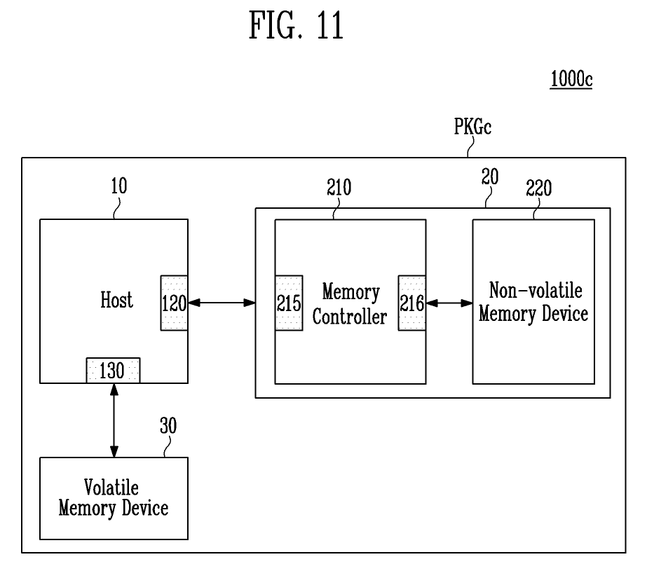

FIG. 11 is a block diagram of an electronic device 1000c according to a third embodiment of the present disclosure.

Referring to FIG. 11, the host 10, the storage device 20, and the volatile memory device 30 may be included in a package PKGc.

The host 10, the storage device 20, and the volatile memory device 30 of FIG. 11 are similar to the host 10, the storage device 20, and the volatile memory device 30 of FIG. 1, and thus repetitive descriptions are omitted.

The electronic device 1000c may include the package PKGc including the host 10, the storage device 20, and the volatile memory device 30.

As the host 10 and the storage device 20 are included in one package PKGc, the host 10 and the storage device 20 may transmit and receive signals to and from each other via lines on a substrate included in the package PKGc. In an embodiment, the host 10 and the storage device 20 may communicate via the device interface circuit 120 of the host 10 and the device interface circuit 215 of the memory controller 210.

As described with reference to FIG. 6, each of the device interface circuit 120 of the host 10 and the device interface circuit 215 of the memory controller 210 may be implemented based on an interface which supports die-to-die communication. For example, each of the device interface circuit 120 of the host 10 and the device interface circuit 215 of the memory controller 210 may be implemented based on UCIe.

The storage device 20 may have a structure in which a plurality of dies are stacked. Further, the storage device 20 may include a vertical connector which is connected to the plurality of dies. The detailed structure of the storage device 20 may be similar to that described with reference to FIGS. 3 to 5.

The volatile memory device 30 may have a structure in which a plurality of dies are stacked. Further, the volatile memory device 30 may include a vertical connector which is connected to the plurality of dies.

The storage device 20 may include the memory controller 210 and the non-volatile memory device 220. The memory controller 210 may communicate with the non-volatile memory device 220 via the non-volatile memory interface circuit 216.

As described with reference to FIG. 7, the memory controller 210 and the non-volatile memory device 220 may perform die-to-die communication via the first data bus, the first data strobe bus, the second data bus, and the second data strobe bus each of which is implemented as a unidirectional bus.

As the host 10 and the volatile memory device 30 are included in one package PKGc, the host 10 and the volatile memory device 30 may transmit and receive signals to and from each other via lines on the substrate included in the package PKGc. In an embodiment, the host 10 may communicate with the volatile memory device 30 via the memory interface circuit 130.

The memory interface circuit 130 of the host 10 may be implemented based on an interface which supports die-to-die communication. For example, the memory interface circuit 130 may be implemented based on UCIe.

The electronic device 1000c, which includes the host 10, the storage device 20, and the volatile memory device 30 included in one package PKGc, may provide higher bandwidth and a faster data transfer speed than an electronic device which supports inter-package communication, and may be suitable for real-time processing.

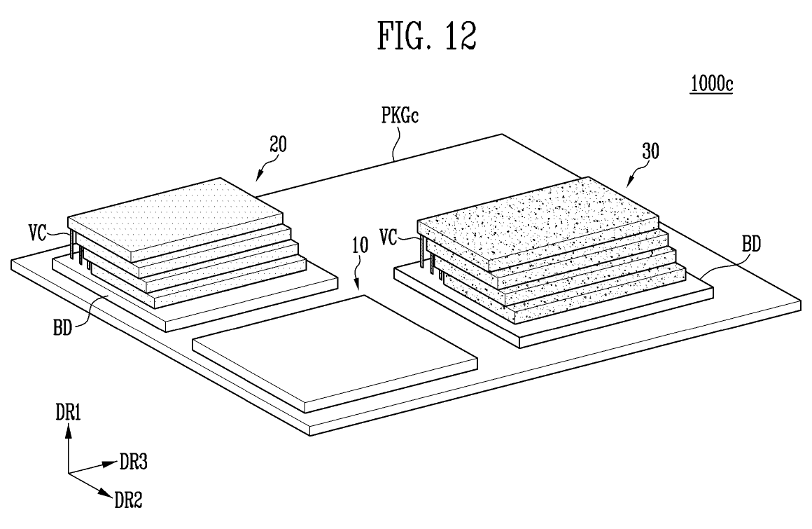

FIG. 12 is a perspective view of the electronic device 1000c according to the third embodiment of the present disclosure.

Referring to FIG. 12, the electronic device 1000c may include the host 10, the storage device 20, and the volatile memory device 30 included in one package PKGc.

The host 10, the storage device 20, and the volatile memory device 30 of FIG. 12 may be similar to the host 10, the storage device 20, and the volatile memory device 30 of FIG. 11. Accordingly, repetitive descriptions may be omitted.

Additionally, the host 10 and the storage device 20 of FIG. 12 may have a similar structure to the host 10 and the storage device 20 of FIG. 4. Alternatively, the host 10 and the storage device 20 of FIG. 12 may have a similar structure to the host 10 and the storage device 20 of FIG. 5. Accordingly, repetitive descriptions may be omitted.

The host 10, the storage device 20, and the volatile memory device 30 may be included in the package PKGc, i.e., the host 10, the storage device 20, and the volatile memory device 30 may be included in a single package substrate. For example, the package substrate SB shown in FIGS. 4 and 5 may include the host 10, the storage device 20, and the volatile memory device 30.

In an embodiment, the package substrate SB may provide a communication path between the host 10 and the storage device 20. The package substrate SB may provide a communication path between the host 10 and the volatile memory device 30.

The storage device 20 may have a structure in which the plurality of memory dies and the base die BD are stacked, and may include the vertical connector VC connected to the plurality of memory dies. The vertical connector VC may extend vertically in the first direction DR1.

The volatile memory device 30 may have a structure in which the plurality of memory dies and the base die BD are stacked, and may include the vertical connector VC connected to the plurality of memory dies. The volatile memory device 30 may have a stacked structure similar to that of the storage device 20 shown in FIG. 3.

Also, for convenience of illustration, the base die BD of FIG. 12 may be represented in a configuration which includes the base die BD, the redistribution layer RDL, and the insulating layer ISL shown in FIGS. 3 to 5.

As the host 10, the storage device 20, and the volatile memory device 30 are included in the same package, the host 10, the storage device 20, and the volatile memory device 30 may transmit and receive signals to and from each other via lines on the substrate included in the package PKGc, i.e., the host 10 and the storage device 20 may perform die-to-die communication, and the host 10 and the volatile memory device 30 may perform die-to-die communication.

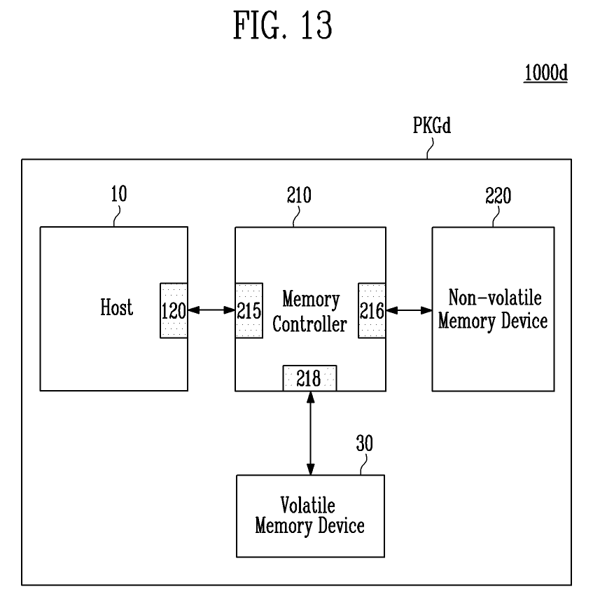

FIG. 13 is a block diagram of an electronic device 1000d according to a fourth embodiment of the present disclosure.

Referring to FIG. 13, the host 10, the memory controller 210, the non-volatile memory device 220, and the volatile memory device 30 may be included in a package PKGd.

The host 10, the memory controller 210, the non-volatile memory device 220, and the volatile memory device 30 of FIG. 13 are similar to the host 10, the memory controller 210, the non-volatile memory device 220, and the volatile memory device 30 of FIG. 1, and therefore repetitive descriptions are omitted.

The electronic device 1000d may include the host 10, the memory controller 210, the non-volatile memory device 220, and the volatile memory device 30 included in the package PKGd.

As the host 10, the memory controller 210, the non-volatile memory device 220, and the volatile memory device 30 are included in one package PKGd, the host 10, the memory controller 210, the non-volatile memory device 220, and the volatile memory device 30 may transmit and receive signals to and from each other via lines on a substrate included in the package PKGd.

In an embodiment, the non-volatile memory device 220 and the volatile memory device 30 may communicate with the host 10 via the memory controller 210.

As described with reference to FIG. 6, each of the device interface circuit 120 of the host 10 and the device interface circuit 215 of the memory controller 210 may be implemented based on an interface which supports die-to-die communication. For example, each of the device interface circuit 120 of the host 10 and the device interface circuit 215 of the memory controller 210 may be implemented based on UCIe.

The non-volatile memory device 220 may have a structure in which a plurality of memory dies are stacked. Further, the plurality of memory dies may be connected to a base die or substrate via a vertical connector.

The volatile memory device 30 may have a structure in which a plurality of memory dies are stacked. Further, the volatile memory device 30 may include a vertical connector which is connected to the plurality of memory dies.

The memory controller 210 may communicate with the non-volatile memory device 220 via the non-volatile memory interface circuit 216.

As described with reference to FIG. 7, the memory controller 210 and the non-volatile memory device 220 may perform die-to-die communication via the first data bus, the first data strobe bus, the second data bus, and the second data strobe bus each of which is implemented as a unidirectional bus.

In an embodiment, the memory controller 210 may communicate with the volatile memory device 30 via the memory interface circuit 218.

The electronic device 1000d, which includes the host 10, the memory controller 210, the non-volatile memory device 220, and the volatile memory device 30 in one package PKGd, may provide higher bandwidth and a faster data transfer speed than an electronic device which supports inter-package communication, and may be suitable for real-time processing.

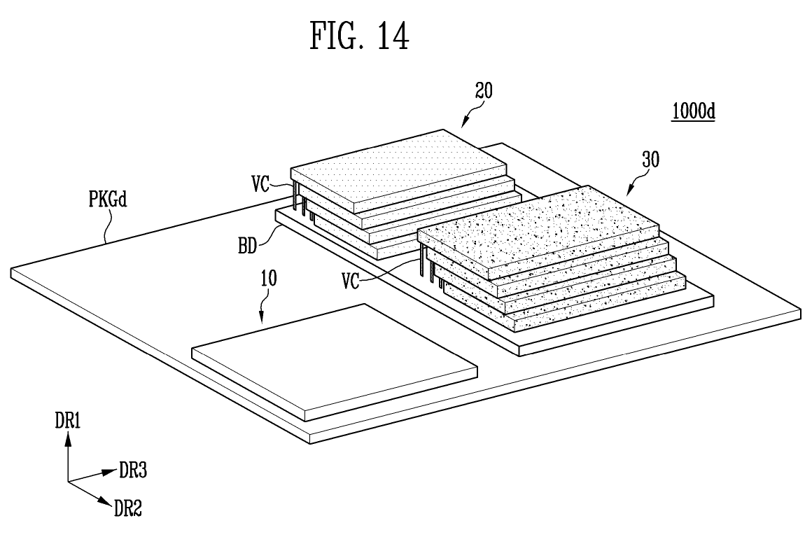

FIG. 14 is a perspective view of the electronic device 1000d according to the fourth embodiment of the present disclosure.

Referring to FIG. 14, the electronic device 1000d may include the host 10, the storage device 20, and the volatile memory device 30 included in one package PKGd.

The host 10 and the volatile memory device 30 of FIG. 14 may be similar to the host 10 and the volatile memory device 30 of FIG. 13. The storage device 20 of FIG. 14 may include the memory controller 210 and the non-volatile memory device 220 of FIG. 13. Accordingly, repetitive descriptions may be omitted.

The storage device 20 may have a similar structure to the storage device 20 of FIG. 3. For convenience of illustration, the base die BD of FIG. 14 may be represented in a configuration which includes the base die BD, the redistribution layer RDL, and the insulating layer ISL shown in FIGS. 3 to 5. Accordingly, repetitive descriptions may be omitted.

The electronic device 1000d may include the host 10, the storage device 20, and the volatile memory device 30 included in the package PKGd, i.e., the host 10, the storage device 20, and the volatile memory device 30 may be included in a single package substrate.

The storage device 20 and the volatile memory device 30 may share the base die BD, i.e., the memory dies of the storage device 20 and the memory dies of the volatile memory device 30 may be arranged on the same base die BD. The storage device 20 may have a structure with the plurality of memory dies stacked on the base die BD, and may include the vertical connector VC connected to the plurality of memory dies. The vertical connector VC may extend vertically in the first direction DR1.

The volatile memory device 30 may have a structure with the plurality of memory dies stacked on the base die BD, and may include the vertical connector VC connected to the plurality of memory dies. The volatile memory device 30 may have a stacked structure similar to that of the plurality of memory dies MD1, MD2, MD3, and MD4 shown in FIG. 3.

As the memory dies of the storage device 20 and the memory dies of the volatile memory device 30 are arranged on the same base die BD, the storage device 20 and the volatile memory device 30 may communicate with the host 10 via a memory controller included in the base die BD.

Referring to FIG. 13, the non-volatile memory device 220 may communicate with the host 10 via the non-volatile memory interface circuit 216, and the device interface circuit 215 of the memory controller 210 included in the base die BD. The volatile memory device 30 may communicate with the host 10 via the memory interface circuit 218 and the device interface circuit 215 of the memory controller 210 included in the base die BD.

That is, as the host 10, the storage device 20, and the volatile memory device 30 are included in the same package, the host 10, the storage device 20, and the volatile memory device 30 may transmit and receive signals to and from each other via lines on the substrate included in the package PKGd. The substrate included in the package PKGd may provide a communication path between the storage device 20 and the host 10 and a communication path between the volatile memory device 30 and the host 10. The host 10, the non-volatile memory device 220, and the volatile memory device 30 may perform die-to-die communication.

According to some embodiments of the present disclosure, as a host and a storage device included in the same package perform die-to-die communication, an electronic device which provides high bandwidth and a fast data transfer speed is provided.

The above description merely provides an illustrative explanation of the present disclosure. Accordingly, a person of ordinary skill in the art to which the present disclosure pertains can make various modifications and variations without departing from the essential characteristics of the present disclosure. In addition, the embodiments disclosed in the present disclosure are not intended to limit the scope of the present disclosure but rather to explain it. Therefore, the scope of the present disclosure should not be limited by the embodiments. The scope of protection of this disclosure shall be construed by the appended claims, and all technical spirits within an equivalent scope shall be construed to be included within the scope of this disclosure.

What is claimed is:

1. An electronic device comprising:
a first package substrate;
a storage device including a plurality of memory dies stacked over the first package substrate and a vertical connector connected to the plurality of memory dies; and
a host disposed on the first package substrate, and configured to control the storage device,
wherein the storage device and the host are configured to communicate within the first package substrate.

2. The electronic device of claim 1, wherein the storage device comprises:
an insulating layer including a redistribution layer;
a base die disposed on the insulating layer;
the plurality of memory dies disposed on the base die; and
the vertical connector configured to connect the plurality of memory dies and the redistribution layer.

3. The electronic device of claim 2, wherein the vertical connector is disposed to extend in a straight line in a direction perpendicular to the first package substrate.

4. The electronic device of claim 3,
wherein the insulating layer further includes a first interface circuit configured to support die-to-die communication with the host, and
wherein the insulating layer is disposed on the first package substrate.

5. The electronic device of claim 4, wherein the first package substrate, the first interface circuit, and a second interface circuit disposed in the host provide a communication path between the host and the storage device.

6. The electronic device of claim 4, further comprising an interposer substrate disposed on the first package substrate,
wherein the storage device and the host are disposed on the interposer substrate.

7. The electronic device of claim 6,
wherein the insulating layer is disposed between the first package substrate and the interposer substrate, and
wherein the interposer substrate, the first interface circuit, and a second interface circuit disposed in the host provide a communication path between the host and the storage device.

8. The electronic device of claim 5, wherein the host and the storage device communicate based on a same protocol layer.

9. The electronic device of claim 8,
wherein the same protocol layer includes one of a network layer supporting an Advanced eXtensible Interface (Axi), a data link layer supporting Universal Chiplet Interconnect Express (UCIe), and a physical layer, and
wherein the first and second interface circuits support UCIe-based communication.

10. The electronic device of claim 9,
wherein the storage device includes a memory controller corresponding to the base die and a non-volatile memory device corresponding to the plurality of memory dies, and
wherein the memory controller and the non-volatile memory device are configured to communicate a data signal and a data strobe signal via unidirectional buses.

11. The electronic device of claim 10,
wherein the memory controller is configured to output a first data signal to the non-volatile memory device via a first data bus, and output a first data strobe signal to the non-volatile memory device via a first data strobe bus, and
wherein the non-volatile memory device is configured to output a second data signal to the memory controller via a second data bus, and output a second data strobe signal to the memory controller via a second data strobe bus.

12. The electronic device of claim 11,
wherein the first data bus includes first data pins and a first transmission line,
wherein the first data strobe bus includes first data strobe pins and a second transmission line,
wherein the second data bus includes second data pins and a third transmission line, and
wherein the second data strobe bus includes second data strobe pins and a fourth transmission line.

13. The electronic device of claim 12,
wherein the first data signal includes at least one of a) a command instructing an operation to be performed by the non-volatile memory device, b) address information for accessing the non-volatile memory device, and c) write data to be stored in the non-volatile memory device,
wherein the first data strobe signal is a timing reference signal output from the memory controller to the non-volatile memory device along with the first data signal,
wherein the second data signal includes at least one of d) an indication of whether the operation corresponding to the command has been completed, e) an indication of whether an error has occurred, f) identification data of the non-volatile memory device, and g) read data read from the non-volatile memory device, and
wherein the second data strobe signal is a timing reference signal output from the non-volatile memory device to the memory controller along with the second data signal.

14. The electronic device of claim 13, further comprising a second package substrate including a volatile memory device configured to communicate with the host.

15. The electronic device of claim 13, further comprising a second package substrate including a volatile memory device configured to communicate with the storage device.

16. The electronic device of claim 13,
wherein the first package substrate further includes a volatile memory device,
wherein the volatile memory device includes a plurality of memory dies which are stacked and a vertical connector connected to the plurality of memory dies, and
wherein the first package substrate provides a communication path between the host and the volatile memory device.

17. The electronic device of claim 16, wherein the host includes a third interface circuit supporting UCIe, and is configured to communicate with the volatile memory device via the third interface circuit.

18. The electronic device of claim 13, further comprising a volatile memory device disposed on the base die,
wherein the volatile memory device includes a plurality of memory dies which are stacked and a vertical connector connected to the plurality of memory dies.

19. The electronic device of claim 18, wherein the first package substrate provides a communication path between the volatile memory device and the host.

20. The electronic device of claim 1, wherein the plurality of memory dies are stacked with an offset.
